(19) United States
(12) Patent Application Publication
(10) Pub. No.: US 2026/0293694 A1
(43) Pub. Date: Sep. 24, 2026

(54) SEMICONDUCTOR PACKAGE

(71) Applicant: LG INNOTEK CO., LTD., Seoul (KR)

(72) Inventors: Min Kyeong JUNG, Seoul (KR); Soon Gyu KWON, Seoul (KR); Hye Jin LEE, Seoul (KR)

(21) Appl. No.: 18/868,831

(22) PCT Filed: May 25, 2023
(86) PCT No.: PCT/KR2023/007167

§ 371 Date: Nov. 25, 2024

(30) Foreign Application Priority Data
May 25, 2022 (KR) 10-2022-0063897

(51) Int. Cl. H10W 44/00; H10W 70/65; H10W 74/10

(52) U.S. Cl. CPC H10W 44/501; H10W 44/601; H10W 70/65; H10W 74/114

(57) ABSTRACT

A semiconductor package according to an embodiment includes a first substrate including first and second pads; a first connection part disposed on the first pad of the first substrate; a second substrate coupled to the first connection part; a second connection part disposed on the second pad of the first substrate; a device mounted on the second connection part; and a molding layer disposed on the first substrate and molding the device, wherein the device includes one of a capacitor and an inductor, and the second substrate includes a pattern layer having a different function from the device.

### TECHNICAL FIELD

An embodiment relates to a semiconductor package, and more particularly to a semiconductor package including an inductor substrate.

### BACKGROUND ART

A current electronic product market is rapidly increasing in demand for portable devices, and to satisfy this demand, a miniaturization of components mounted in a system is essential.

In order to realize the miniaturization of the components, a technology for reducing individual sizes of the mounted components, SOC (System On Chip) technology for integrating multiple individual devices into a single chip, and SIP (System In Package) technology for integrating multiple individual devices into a single package, etc. are required.

Recently, in accordance with a trend of multi-functionality and miniaturization of mobile communication terminals such as mobile phones, PDAs (Personal Digital Assistants), smart phones, and various media terminals, various components mounted in terminals or modules installed in headsets are being developed in a miniaturization trend. In order to miniaturize these modules, research is being conducted to implement components such as RF (Radio Frequency) devices and IC chips into a single package.

Accordingly, a conventional semiconductor package is mounting integrated passive devices (IPDs) on a substrate to reduce an overall volume. However, when a plurality of integrated passive devices are disposed on a single substrate, electrical reliability problems occur due to interference between them.

### DISCLOSURE

### Technical Problem

The embodiment provides a semiconductor package having improved electrical reliability.

In addition, the embodiment provides a semiconductor package in which a second substrate having a function of a second device is disposed on a first substrate having a first device disposed thereon, thereby minimizing interference between the first device and the second device.

In addition, the embodiment provides a semiconductor package capable of dramatically reducing a thickness of the second substrate having a function of a second device.

In addition, the embodiment provides a semiconductor package including a second substrate having a plurality of coil patterns having different inductance values formed on one insulating layer.

In addition, the embodiment provides a semiconductor package capable of reducing a thickness.

Technical problems to be solved by the proposed embodiments are not limited to the above-mentioned technical problems, and other technical problems not mentioned can be clearly understood by those skilled in the art to which the embodiments proposed from the following descriptions belong.

### Technical Solution

A semiconductor package according to an embodiment comprises a first substrate including first and second pads; a first connection part disposed on the first pad of the first substrate; a second substrate coupled to the first connection part; a second connection part disposed on the second pad of the first substrate; a device mounted on the second connection part; and a molding layer disposed on the first substrate and molding the device, wherein the device includes one of a capacitor and an inductor, and the second substrate includes a pattern layer having a different function from the device.

In addition, the second substrate includes: a second insulating layer; a second circuit pattern disposed on the second insulating layer and corresponding to the pattern layer; and a second through electrode penetrating the second insulating layer.

In addition, the second substrate further includes a second protective layer disposed at upper and lower surfaces of the second insulating layer, and the molding layer molds the device at a position spaced apart from the second substrate.

In addition, the molding layer molds the second insulating layer and the second circuit pattern of the second substrate.

In addition, the second substrate is an inductor substrate including a coil pattern forming an inductance, and the device includes: a first device corresponding to a capacitor; and a second device spaced apart from the first device and corresponding to an inductor.

In addition, the second substrate is a capacitor substrate including a capacitor pattern forming a capacitance, and the device includes: a first device corresponding to a capacitor; and a second device spaced apart from the first device and corresponding to an inductor.

In addition, the second circuit pattern includes a first pattern layer disposed on an upper surface of the second insulating layer, and a second pattern layer disposed on a lower surface of the second insulating layer, wherein the first pattern layer includes a plurality of coil patterns, and the plurality of coil patterns include a first coil pattern having a first separation distance from the second pattern layer, and a second coil pattern having a second separation distance different from the first separation distance from the second pattern layer.

In addition, the first coil pattern is disposed in a pattern recess formed at an upper surface of the second insulating layer, and the second coil pattern protrudes on an upper surface of the second insulating layer.

In addition, the first coil pattern is disposed in a first recess having a first depth formed at an upper surface of the second insulating layer, and the second coil pattern is disposed in a second recess having a second depth different from the first depth formed at the upper surface of the second insulating layer.

In addition, the second insulating layer includes a PID (Photo Imageable Dielectric resin).

### Advantageous Effects

The semiconductor package of the embodiment includes a first substrate and a second substrate. In addition, the semiconductor package includes at least one device mounted on the first substrate. In addition, the second substrate is mounted on the first substrate and can perform an inductor function or a capacitor function.

Specifically, the embodiment configures one of the inductor and the capacitor as a die-type device, and other one of the inductor and the capacitor as a substrate-type device. Accordingly, the embodiment can secure a design space of the semiconductor package and thereby secure design freedom. Furthermore, the embodiment implements an inductor and a capacitor in different types to solve the reliability problem that may occur between the inductor and the capacitor. For example, when the inductor and the capacitor are disposed adjacent to each other, there may be a problem that the characteristics of each function are deteriorated due to the interference therebetween. Accordingly, the embodiment implements an inductor and a capacitor in different types, and it is possible to solve the problem that the characteristics of each function are deteriorated. Furthermore, the embodiment may maximize characteristics of an inductor function and a capacitor function, thereby further improving product reliability.

In addition, the embodiment includes a plurality of inductors or a plurality of capacitors. In addition, one inductor of the plurality of inductors is configured as a die-type device, and other inductor of the plurality of inductors is configured as a substrate-type device. In addition, in the embodiment, one capacitor of the plurality of capacitors is configured as a die-type device, and the other capacitor of the plurality of capacitors is configured as a substrate-type device.

Accordingly, the embodiment can further maximize the inductor function or the capacitor function, and thus further improve the product performance.

In addition, the second substrate of the embodiment includes a second insulating layer including a photosensitive material. In addition, a pattern layer of the second substrate is inserted into a recess of the second insulating layer or has a protruding structure. In addition, the recess of the second insulating layer can include a plurality of recesses having different depths, and the pattern layer can be respectively disposed in the plurality of recesses. Through this, the embodiment can implement a plurality of inductances in one second substrate. Accordingly, the embodiment can further improve the product performance.

### DESCRIPTION OF DRAWINGS

FIG. 1 is a drawing showing a semiconductor package according to a first embodiment.

FIG. 2 is a drawing showing a semiconductor package according to a second embodiment.

FIG. 3a is a drawing showing a first pattern layer of a second circuit pattern of a second substrate of FIG. 1 or FIG. 2.

FIG. 3b is a drawing showing a second pattern layer of a second circuit pattern of a second substrate of FIG. 1 or FIG. 2.

FIG. 3c is a drawing showing a third pattern layer of a second circuit pattern of a second substrate of FIG. 1 or FIG. 2.

FIG. 4 is a drawing showing a specific layer structure of a second substrate according to a first embodiment.

FIG. 5 is a drawing showing a specific layer structure of a second substrate according to a second embodiment.

FIG. 6 is a drawing showing a specific layer structure of a second substrate according to a third embodiment.

FIG. 7 is a drawing showing a specific layer structure of a second substrate according to a fourth embodiment.

### BEST MODE

Hereinafter, embodiments of the present disclosure will be described in detail with reference to the accompanying drawings.

However, the spirit and scope of the present disclosure is not limited to a part of the embodiments described, and can be implemented in various other forms, and within the spirit and scope of the present disclosure, one or more of the elements of the embodiments can be selectively combined and redisposed.

In addition, unless expressly otherwise defined and described, the terms used in the embodiments of the present disclosure (including technical and scientific terms) can be construed the same meaning as commonly understood by one of ordinary skill in the art to which the present disclosure belongs, and the terms such as those defined in commonly used dictionaries can be interpreted as having a meaning that is consistent with their meaning in the context of the relevant art. In addition, the terms used in the embodiments of the present disclosure are for describing the embodiments and are not intended to limit the present disclosure.

In this specification, the singular forms can also include the plural forms unless specifically stated in the phrase, and can include at least one of all combinations that can be combined in A, B, and C when described in “at least one (or more) of A (and), B, and C”. Further, in describing the elements of the embodiments of the present disclosure, the terms such as first, second, A, B, (a), and (b) can be used.

These terms are only used to distinguish the elements from other elements, and the terms are not limited to the essence, order, or order of the elements. In addition, when an element is described as being “connected”, “coupled”, or “contacted” to another element, it can include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” can include not only when two elements are directly connected to each other, but also when one or more other elements are formed or disposed between two elements. Further, when expressed as “on (over)” or “under (below)”, it can include not only the upper direction but also the lower direction based on one element.

### Electronic Device

Before describing an embodiment, an electronic device to which a semiconductor package of the embodiment is applied will be briefly described. An electronic device includes a main board (not shown). The main board can be physically and/or electrically connected to various components. For example, the main board can be connected to the semiconductor package of the embodiment. Various semiconductor devices can be mounted on the semiconductor package. Broadly, the various semiconductor devices mounted on the semiconductor package can include a memory chip such as a volatile memory (e.g., DRAM), a non-volatile memory (e.g., ROM), and a flash memory, an application processor chip such as a central processor (e.g., CPU), a graphics processor (e.g., GPU), a digital signal processor, a cryptographic processor, a microprocessor, and a microcontroller, and a logic chip such as an analog-to-digital converter and an application-specific IC (ASIC).

In addition, the device or the chip may include passive devices and active devices.

The active device refers to a component that actively utilizes a nonlinear portion of the signal characteristics. In addition, the passive device refers to a component that does not utilize the nonlinear signal characteristics even though both linear and nonlinear signal characteristics exist. For example, the active device may include a transistor, an IC semiconductor device, and the passive device may include a capacitor, a resistor, an inductor, and the like. The passive device may increase the signal processing speed of the semiconductor chip, which is the active device, or perform a filtering function. In addition, the chip may be a wireless communication chip that can be used for Wi-Fi or 5G communication.

Meanwhile, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package On Package), and SIP (System In Package), but is not limited thereto.

In this case, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

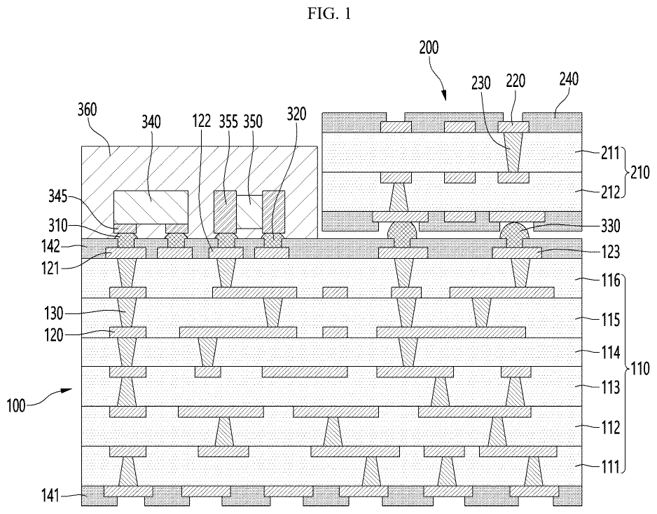

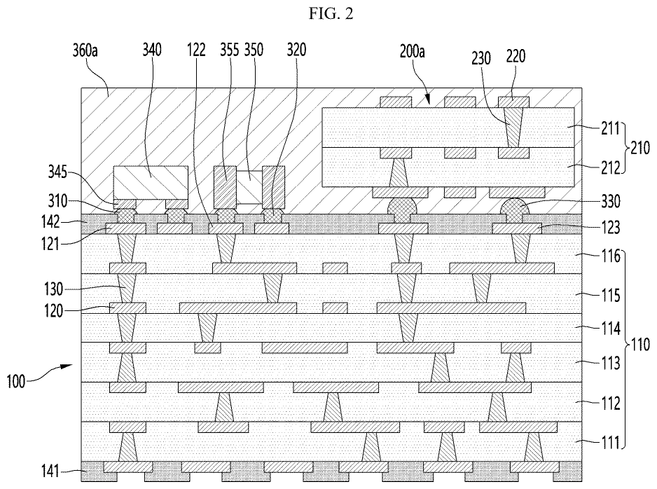

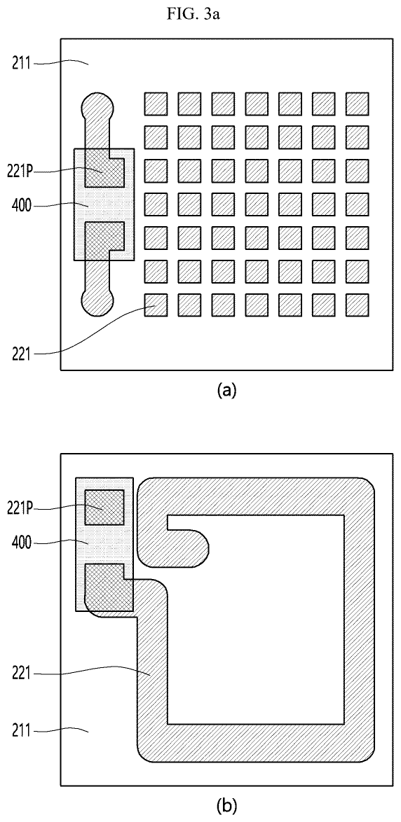

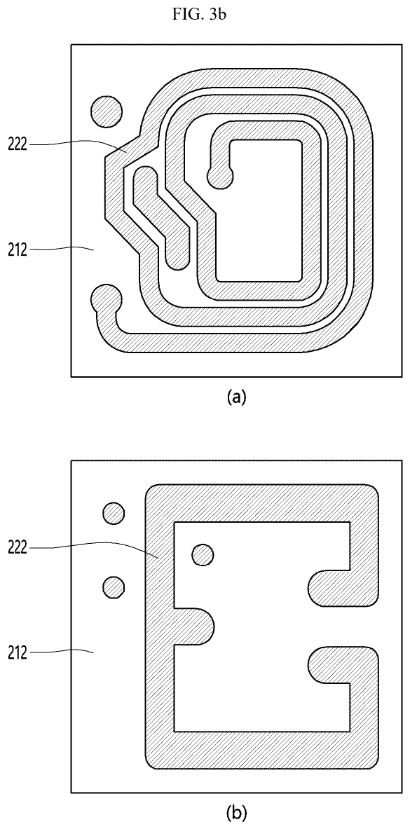

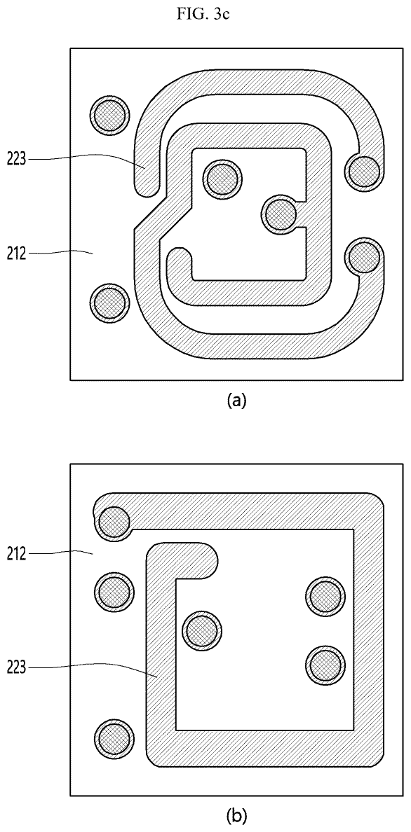

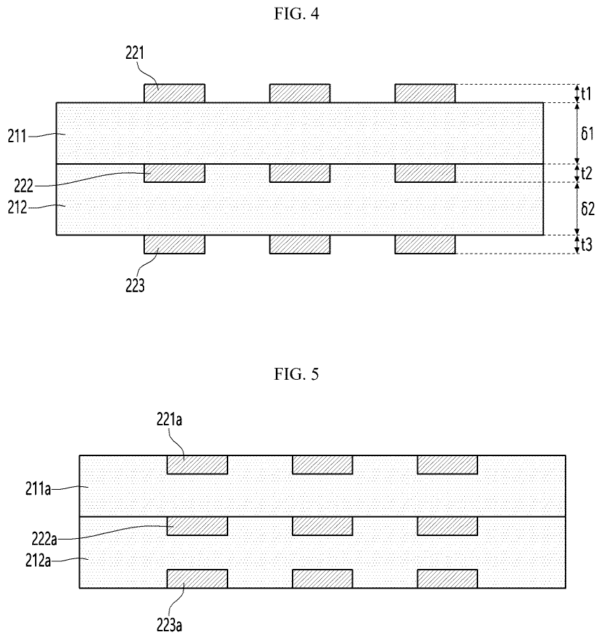

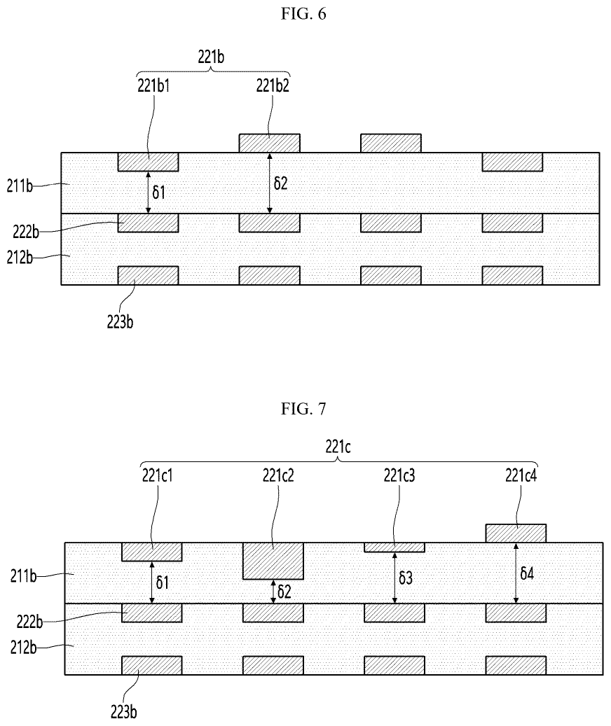

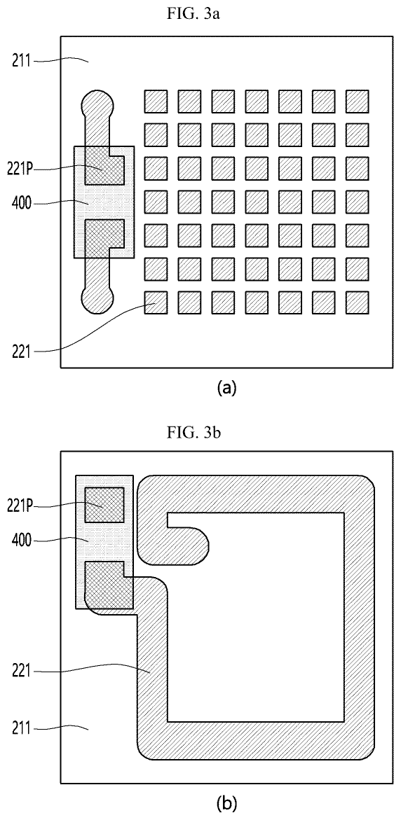

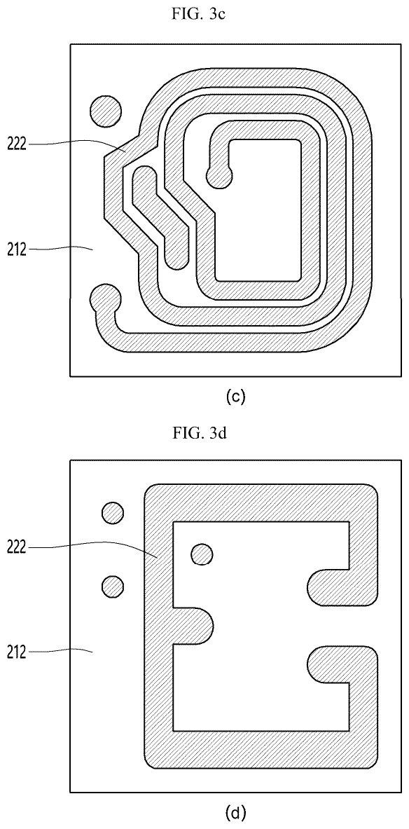

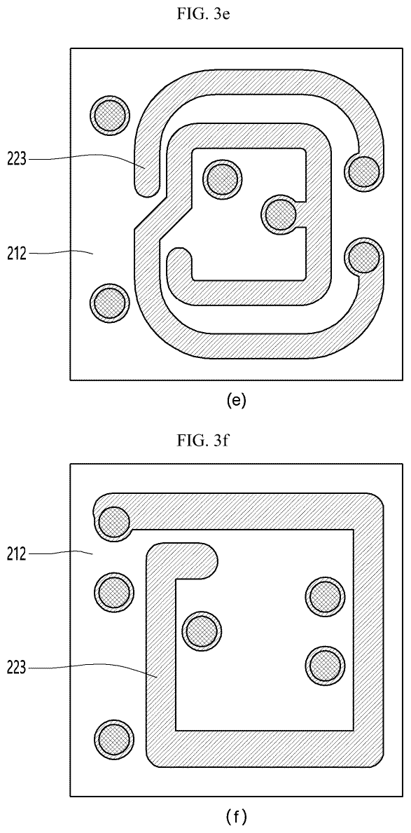

FIG. 1 is a drawing showing a semiconductor package according to a first embodiment, FIG. 2 is a drawing showing a semiconductor package according to a second embodiment, FIG. 3a is a drawing showing a first pattern layer of a second circuit pattern of a second substrate of FIG. 1 or FIG. 2, FIG. 3b is a drawing showing a second pattern layer of a second circuit pattern of a second substrate of FIG. 1 or FIG. 2, and FIG. 3c is a drawing showing a third pattern layer of a second circuit pattern of a second substrate of FIG. 1 or FIG. 2.

Referring to FIGS. 1 to 3c, the semiconductor package of the embodiment includes a first substrate 100 and a second substrate 200. The first substrate 100 includes a plurality of pads. In addition, the semiconductor package of the embodiment may include a device disposed on at least one of the plurality of pads of the first substrate 100. For example, the semiconductor package of the embodiment may include a first device 300 and a second device 400 mounted on the first substrate 100.

The first substrate 100 may have a plurality of layer structures.

The first substrate 100 may have a six-layer structure based on a number of layers of an insulating layer. However, the embodiment is not limited thereto.

For example, the first substrate 100 may have a layer structure of five or less layers based on the number of layers of the insulating layer. Unlike this, the first substrate 100 may have a layer structure of seven or more layers based on the number of layers of the insulating layer. Hereinafter, for the convenience of explanation, the first substrate 100 is described as having a six-layer structure based on the number of layers of the insulating layer.

The first substrate 100 includes a first insulating layer 110. The first insulating layer 110 may have a six-layer structure.

For example, the first insulating layer 110 may include, from a bottom, a first-first insulating layer 111, a first-second insulating layer 112, a first-third insulating layer 113, a first-fourth insulating layer 114, a first-fifth insulating layer 115, and a first-sixth insulating layer 116. The first-second insulating layer 112, the first-third insulating layer 113, the first-fourth insulating layer 114, and the first-fifth insulating layer 115 may be inner insulating layers disposed in an inner layer in a laminated structure of the first substrate 100. In addition, the first-first insulating layer 111 may be a first outer insulating layer disposed at a lowermost side in the laminated structure of the first substrate 100. In addition, the first-sixth insulating layer 116 may be a second outer insulating layer disposed at an uppermost side in the laminated structure of the first substrate 100.

The first insulating layer 110 is a substrate on which an electric circuit capable of changing wiring is formed, and may include all of a print, a wiring board, and an insulating substrate made of an insulating material capable of forming a circuit pattern on a surface.

The first insulating layer 110 may be rigid or flexible. For example, the first insulating layer 110 may include glass or plastic. In detail, the first insulating layer 110 may include chemically strengthened/semi-strengthened glass such as soda lime glass or aluminosilicate glass. Alternatively, the first insulating layer 110 may include a reinforced or flexible plastic such as polyimide (PI), polyethylene terephthalate (PET), propylene glycol (PPG), or polycarbonate (PC). Alternatively, the first insulating layer 110 may include sapphire.

In addition, the first insulating layer 110 may include an optically isotropic film. For example, the first insulating layer 110 may include COC (Cyclic Olefin Copolymer), COP (Cyclic Olefin Polymer), optically isotropic polycarbonate (PC), or optically isotropic polymethyl methacrylate (PMMA).

In addition, the first insulating layer 110 may be formed of a material including an inorganic filler and an insulating resin. For example, the first insulating layer 110 may include a structure in which an inorganic filler such as silica or alumina is dispersed in a thermosetting resin such as an epoxy resin or a thermoplastic resin such as a polyimide. For example, the first insulating layer 110 may include ABF (Ajinomoto Build-up Film), FR-4, BT (Bismaleimide Triazine), PID (Photo Imageable Dielectric resin), BT, etc.

In addition, the first insulating layer 110 may be bent while partially having a curved surface. That is, the first insulating layer 110 may be bent while partially having a plane and partially having a curved surface. In detail, the first insulating layer 110 may be bent while having a curved end or may be bent or curved while having a surface including a random curvature.

In addition, the first insulating layer 110 may be a flexible substrate having flexible characteristics. In addition, the first insulating layer 110 may be a curved or bent substrate. At this time, the first insulating layer 110 expresses electrical wiring connecting circuit components based on a circuit design as a wiring diagram, and can reproduce an electrical conductor on the insulating material. In addition, the first insulating layer 110 may mount a device and form a wiring that electrically connects them. In addition, the first insulating layer 110 may mechanically fix the devices in addition to the electrical connection function of the devices.

Each layer of the first insulating layer 110 may have a thickness in a range of 10 μm to 60 μm. Preferably, each layer of the first insulating layer 110 may have a thickness in a range of 12 μm to 50 μm. More preferably, each layer of the first insulating layer 110 may have a thickness in a range of 15 μm to 40 μm.

If the thickness of at least one layer among each layer of the first insulating layer 110 is less than 10 μm, the circuit pattern on the first substrate 100 may not be stably protected. If the thickness of at least one layer among each layer of the first insulating layer 110 exceeds 60 μm, a thickness of the first substrate 100 and a thickness of the semiconductor package including the same may increase. In addition, if a thickness of at least one layer among each layer of the first insulating layer 110 exceeds 60 μm, a thickness of a circuit pattern and a thickness of a through electrode may increase correspondingly. In addition, if the thickness of the circuit pattern and the thickness of the through electrode increase, the signal transmission loss may increase.

Meanwhile, the first substrate 100 may be a coreless substrate, but is not limited thereto. For example, the first substrate 100 may be a core substrate. In addition, when the first substrate 100 is a core substrate, at least one of the inner layer insulating layers of the first insulating layer 110 may be a core layer. In addition, the core layer may have a greater thickness than other layers of the first insulating layer 110.

The first substrate 100 includes a first circuit pattern 120 disposed on the first insulating layer 110. The first circuit pattern 120 may be disposed on a surface of each layer of the first insulating layer 110.

The first circuit pattern 120 may be formed of a metal material having high electrical conductivity as a wiring for transmitting an electrical signal. To this end, the first circuit pattern 120 may be formed of at least one metal material selected from gold (Au), silver (Ag), platinum (Pt), titanium (Ti), tin (Sn), copper (Cu), and zinc (Zn). In addition, the first circuit pattern 120 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first circuit pattern 120 may be formed of copper (Cu) having high electrical conductivity and a relatively low price.

The first circuit pattern 120 may be formed by a conventional manufacturing process of a printed circuit board, such as an additive process, a subtractive process, a modified semi-additive process (MSAP), and a semi-additive process (SAP), and a detailed description thereof is omitted herein.

The first circuit pattern 120 includes a trace and a pad. A trace means a long line-shaped wiring that transmits an electrical signal. In addition, the pad may mean a mounting pad on which a component such as a chip is mounted, a terminal pad or core pad or BGA pad for connection with an external board, or a via pad connected to a via.

Preferably, the first circuit pattern 120 may include a plurality of pads. At this time, the plurality of pads may mean a part of the first circuit pattern disposed at an uppermost side among the first circuit patterns 120.

The first circuit pattern 120 includes a pad disposed on an upper surface of the first insulating layer 110. For example, the first circuit pattern 120 includes a pad disposed on an upper surface of the first-sixth insulating layer 116 disposed at the uppermost side among the first insulating layer 110.

The first circuit pattern 120 includes a first pad 123. The first pad 123 may function as a bonding pad for bonding the second substrate 200 to the first substrate 100.

The first pad 123 may be formed in multiple numbers on the upper surface of the first insulating layer 110. In addition, the plurality of first pads 123 may be electrically connected to pads (not shown) of the second substrate 200, respectively.

The first circuit pattern 120 may include a second pad 121 disposed on the upper surface of the first insulating layer 110. The second pad 121 may function as a first mounting pad for mounting the first device 340 on the first substrate 100. The second pad 121 may be included in multiple numbers. A number of the second pads 121 may correspond to a number of first terminals 345 of the first device 340. For example, the first device 340 may include two first terminals 345. Accordingly, the second pad 121 may be configured in two numbers.

The first circuit pattern 120 may include a third pad 122 disposed on the upper surface of the first insulating layer 110. The third pad 122 may function as a second mounting pad for mounting the second device 350 on the first substrate 100. The third pad 122 may be included in multiple numbers. A number of the third pads 122 may correspond to a number of second terminals 355 of the second device 350.

The first device 340 and the second device 355 may be active devices, or alternatively, may be passive devices. For example, at least one of the first device 340 and the second device 355 may include an integrated passive device (IPD). For example, the integrated passive device may include a capacitor. For example, at least one of the first device 340 and the second device 355 may be a multilayer ceramic capacitor (MLCC). The multilayer ceramic capacitor may have a two-terminal structure, or alternatively, may have a three-terminal structure. However, the embodiment is not limited thereto. For example, at least one of the first device 340 and the second device 355 may include an inductor. Specifically, the embodiment configures at least one of the capacitor and the inductor as a die-type device. In addition, the embodiment configures at least the other of the capacitor and the inductor as a substrate type.

For example, the second substrate 200 may be an inductor substrate including a coil pattern that functions as an inductor. In this case, at least one of the first device 340 and the second device 355 may include a capacitor.

In addition, the second substrate 200 may be a capacitor substrate including a pattern that functions as a capacitor. In this case, at least one of the first device 340 and the second device 355 may include an inductor.

The semiconductor package of the embodiment includes a first substrate and a second substrate. In addition, the semiconductor package includes at least one device mounted on the first substrate. In addition, the second substrate is mounted on the first substrate and can perform an inductor function or a capacitor function.

Specifically, the embodiment configures one of the inductor and the capacitor as a die-type device, and other one of the inductor and the capacitor as a substrate-type device. Accordingly, the embodiment can secure a design space of the semiconductor package and thereby secure design freedom. Furthermore, the embodiment implements an inductor and a capacitor in different types to solve the reliability problem that may occur between the inductor and the capacitor. For example, when the inductor and the capacitor are disposed adjacent to each other, there may be a problem that the characteristics of each function are deteriorated due to the interference therebetween. Accordingly, the embodiment implements an inductor and a capacitor in different types, and it is possible to solve the problem that the characteristics of each function are deteriorated. Furthermore, the embodiment may maximize characteristics of an inductor function and a capacitor function, thereby further improving product reliability.

In addition, the embodiment includes a plurality of inductors or a plurality of capacitors. In addition, one inductor of the plurality of inductors is configured as a die-type device, and other inductor of the plurality of inductors is configured as a substrate-type device. In addition, in the embodiment, one capacitor of the plurality of capacitors is configured as a die-type device, and the other capacitor of the plurality of capacitors is configured as a substrate-type device.

Accordingly, the embodiment can further maximize the inductor function or the capacitor function, and thus further improve the product performance.

Meanwhile, the first circuit pattern 120 may have a thickness of 10 μm to 25 μm. Preferably, the first circuit pattern 120 may have a thickness of 12 μm to 23 μm. More preferably, the first circuit pattern 120 may have a thickness of 15 μm to 20 μm. If the thickness of the first circuit pattern 120 exceeds 25 μm, it may be difficult to refine a line width or a spacing of the first circuit pattern 120. If the thickness of the first circuit pattern 120 is less than 10 μm, it may be difficult to implement a normal circuit.

The first substrate 100 may include a first through electrode 130. The first through electrode 130 may penetrate the first insulating layer 110. For example, the first through electrode 130 may penetrate at least one insulating layer among a plurality of insulating layers constituting the first insulating layer 110. The first through electrode 130 may individually penetrate each insulating layer constituting the first insulating layer 110. Alternatively, the first through electrode 130 may commonly penetrate at least two insulating layers among the insulating layers constituting the first insulating layer 110.

The first through electrode 130 can be formed by forming a first through hole penetrating the first insulating layer 110 and filling the formed first through hole with a conductive material. The first through hole can be formed by any one of mechanical, laser, and chemical processing methods. The first through hole can be formed by mechanical processing methods such as milling, drilling, and routing. In addition, the first through hole can be formed using a UV or CO2 laser method. In addition, the first through hole can be formed using a chemical processing method using a chemical agent including amino silane, ketones, etc.

When the first through hole is formed, the first through hole can be filled with a conductive material to form the first through electrode 130. The first through electrode 130 may be formed of any one metal material selected from copper (Cu), silver (Ag), tin (Sn), gold (Au), nickel (Ni), and palladium (Pd). In addition, the conductive material filling may utilize any one of electroless plating, electrolytic plating, screen printing, sputtering, evaporation, ink jetting, and dispensing, or a combination thereof.

The first substrate 100 may include a first protective layer. For example, the first substrate 100 may include a first-first protective layer 141 disposed on A lower surface of the first insulating layer 110. In addition, the first substrate 100 may include a first-second protective layer 142 disposed on the upper surface of the first insulating layer 110.

The first protective layer may be disposed to cover the surface of the first insulating layer 110 and the surface of the first circuit pattern 120. In addition, the first protective layer may include an opening that overlaps with at least one of the first circuit patterns 120 in A thickness direction.

For example, the first protective layer may include a first opening that overlaps with the first pad 123 of the first circuit pattern 120 in the thickness direction. In addition, the first protective layer may include a second opening that overlaps the second pad 121 of the first circuit pattern 120 in the thickness direction. In addition, the first protective layer may include a third opening that overlaps the third pad 122 of the first circuit pattern 120 in the thickness direction.

The first protective layer may include an insulating material. The first protective layer may include various materials that can be applied to protect the surface of the first insulating layer 110 and the surface of the first circuit pattern 120 and then cured by heating. The first protective layer may be a resist layer. For example, the first protective layer 150 and the second protective layer 160 may be solder resist layers that include organic polymer materials. As an example, the first protective layer may include an epoxy acrylate series resin. In detail, the first protective layer may include a resin, a curing agent, a photo initiator, a pigment, a solvent, a filler, an additive, an acrylic series monomer, etc. However, the embodiment is not limited thereto, and the first protective layer may be any one of a photo solder resist layer, a cover-lay, and a polymer material.

A thickness of the first protective layer may be 1 μm to 20 μm. The thickness of the first protective layer may be 1 μm to 15 μm. For example, the thickness of the first protective layer may be 5 μm to 20 μm. If the thickness of the first protective layer exceeds 20 μm, the overall thickness of the semiconductor package may increase. In addition, if the thickness of the first protective layer is less than 1 μm, the first circuit pattern 120 of an outermost layer included in the semiconductor package may not be stably protected.

The embodiment may include a second substrate 200, a first device 340, and a second device 355 disposed on the first substrate 100.

At this time, since the first device 340 and the second device 355 have already been described above, detailed descriptions are omitted. Specifically, the first device 340 and the second device 355 may include one of an inductor and a capacitor, and the second substrate 200 may include other one of the inductor and the capacitor. However, the embodiment is not limited thereto.

For example, the semiconductor package of the embodiment may include a plurality of inductors. In addition, at least one of the plurality of inductors of the semiconductor package may be mounted on the first substrate 100 in a die-type, and other one of the plurality of inductors of the semiconductor package may be implemented as the second substrate 200.

In addition, the semiconductor package of the embodiment may include a plurality of capacitors. In addition, at least one of the plurality of capacitors of the semiconductor package may be mounted on the first substrate 100 in a die type, and other one of the plurality of capacitors of the semiconductor package may be implemented as the second substrate 200.

Hereinafter, the second substrate 200 will be described in detail. The second substrate 200 may be a substrate that functions as a capacitor, or may be a substrate that functions as an inductor. For convenience of explanation, the second substrate 200 will be described as a substrate that functions as an inductor. However, the embodiment is not limited thereto.

Referring to FIG. 1, the second substrate 200 may have a structure including a second insulating layer 210, a second circuit pattern 220, a second through electrode 230, and a second protective layer 240.

The second insulating layer 210 may be composed of at least one layer. Preferably, the second insulating layer 210 may have a layer structure of two or more layers. Through this, the embodiment enables implementation of various inductances in the second substrate 200.

The second insulating layer 210 may include a same insulating material as the first insulating layer 110. In contrast, the second insulating layer 210 may include an insulating material different from that of the first insulating layer 110.

The second substrate 200 includes a second circuit pattern 220. The second circuit pattern 220 may be disposed on a surface of the second insulating layer 210. The second circuit pattern 220 may be a pattern having a coil shape.

The second substrate 200 includes a second through electrode 230. The second through electrode 230 passes through the second insulating layer 210.

In addition, the second substrate 200 of the first embodiment of FIG. 1 includes a second protective layer 240. The second protective layer 240 may be disposed on upper and lower surfaces of the second insulating layer 210, respectively.

In contrast, the second substrate 200a of the second embodiment of FIG. 2 may have a structure in which the second protective layer 240 is omitted.

Since the basic characteristics of the second substrate 200 have already been described in the first substrate 100, a detailed description thereof will be omitted.

In addition, the semiconductor package includes a molding layer 360.

The molding layer 360 may be disposed on the first substrate 100.

The molding layer 360 of the first embodiment of FIG. 1 may mold the first device 340 and the second device 350 disposed on the first substrate 100. At this time, the molding layer 360 of the first embodiment may not cover the second substrate 200. That is, the second substrate 200 includes the second protective layer 240, and accordingly, the molding layer 360 can mold only the first device 340 and the second device 350.

However, the embodiment is not limited thereto. For example, the molding layer 360 can mold the second substrate 200 together with the first device 340 and the second device 350.

In addition, the molding layer 360a of the second embodiment of FIG. 2 can mold the second substrate 200. At this time, the second protective layer 240 can be omitted from the second substrate 200. Accordingly, the molding layer 360 can mold the second circuit pattern 220 and the second insulating layer 210 of the second substrate 200.

The molding layer 360 can be EMC (Epoxy Mold Compound), but is not limited thereto.

The molding layer 360 can have a low permittivity in order to improve heat dissipation characteristics. For example, the permittivity (Dk) of the molding layer 360 can be 0.2 to 10. For example, the permittivity (Dk) of the molding layer 360 can be 0.5 to 8. For example, the permittivity (Dk) of the molding layer 360 may be 0.8 to 5. Accordingly, in the embodiment, the molding layer 360 has a low permittivity, thereby improving the heat dissipation characteristics of the first device 340 and the second device 350.

In addition, the semiconductor package includes a plurality of connection parts. For example, the semiconductor package includes a first connection part 330 disposed on a first pad 123 of the first circuit pattern 120.

In addition, the semiconductor package may include a second connection part 310 disposed on a second pad 121 of the first circuit pattern 120.

In addition, the semiconductor package may include a third connection part 320 disposed on a third pad 122 of the first circuit pattern 120.

The first to third connection parts 310, 320, and 330 may include a spherical shape. For example, cross-sections of the first to third connection parts 310, 320, and 330 may include a circular shape or a semicircular shape. For example, cross-sections of the first to third connection parts 310, 320, and 330 may include a partially or entirely rounded shape. Cross-sectional shapes of the first to third connection parts 310, 320, and 330 may be flat at one side and curved at other side. The first to third connection parts 310, 320, and 330 may be solder balls, but are not limited thereto.

In contrast, the first to third connection parts 310, 320, and 330 may have a hexahedral shape. For example, cross-sections of the first to third connection parts 310, 320, and 330 may include a square shape. The cross-sections of the first to third connection parts 310, 320, and 330 may include a rectangle or a square.

Meanwhile, referring to FIGS. 3A to 3C, the second circuit pattern 220 may mean a coil pattern layer respectively disposed on surfaces of multiple insulating layers.

FIG. 3a (a) is a plan view showing a first embodiment of a first pattern layer 221, and FIG. 3a (b) is a plan view showing a second embodiment of a first pattern layer 221.

The first pattern layer 221 of the first embodiment may include a plurality of rectangular patterns spaced apart from each other, as shown in FIG. 3a (a).

Unlike this, the first pattern layer 221 of the second embodiment may have a coil shape.

Meanwhile, the first pattern layer 221 may be connected to a lower second pattern layer 222 through the second through electrode 230. The first pattern layer 221 may include a pad 221P. In addition, a chip 400 may be mounted on the pad 221P of the first pattern layer 221. The chip 400 may be a multilayer ceramic capacitor (MLCC), but is not limited thereto.

Meanwhile, (a) of FIG. 3b illustrates the second pattern layer 222 of the first embodiment connected to the first pattern layer 221 of the first embodiment, and (b) of FIG. 3b illustrates the second pattern layer 222 of the second embodiment connected to the first pattern layer 221 of the second embodiment.

The second pattern layer 222 is disposed on a lower surface of the second-first insulating layer 211 or an upper surface of the second-second insulating layer 212. The second pattern layer 222 has a coil shape. For example, the second pattern layer 222 may include a pattern bended multiple times in one direction on the lower surface of the second-first insulating layer 211 or the upper surface of the second-second insulating layer 212. The second pattern layer 222 may be connected to the first pattern layer 221 and the third pattern layer 223 through the through electrode 230.

Meanwhile, (a) of FIG. 3c illustrates the third pattern layer 223 of the first embodiment, which is connected to the first pattern layer 221 and the second pattern layer 222 of the first embodiment, and (b) of FIG. 3c illustrates the third pattern layer 223 of the second embodiment, which is connected to the first pattern layer 221 and the second pattern layer 222 of the second embodiment.

The third pattern layer 223 is disposed on the lower surface of the second-second insulating layer 212. The third pattern layer 223 may include a pad part connected to the first connection part 330. The third pattern layer 223 has a coil shape. For example, the third pattern layer may include a pattern that is bended multiple times in one direction on the lower surface of the second-second insulating layer 212. The third pattern layer 223 can be connected to the first pattern layer 221 and the second pattern layer 222 through the through electrode 230.

Hereinafter, the second substrate 200 will be described in detail.

FIG. 4 is a drawing showing a specific layer structure of a second substrate according to a first embodiment, FIG. 5 is a drawing showing a specific layer structure of a second substrate according to a second embodiment, FIG. 6 is a drawing showing a specific layer structure of a second substrate according to a third embodiment, and FIG. 7 is a drawing showing a specific layer structure of a second substrate according to a fourth embodiment.

Referring to FIG. 4, the second insulating layer 210 of the second substrate 200 includes a second-first insulating layer 211 and a second-second insulating layer 212.

In addition, the second circuit pattern 220 of the second substrate 200 includes a first pattern layer 221 disposed on the upper surface of the second-first insulating layer 211. In addition, the second circuit pattern 220 includes a second pattern layer 222 disposed between the lower surface of the second-first insulating layer 211 and the upper surface of the second-second insulating layer 212. In addition, the second circuit pattern 220 includes a third pattern layer 223 disposed on a lower surface of the second-second insulating layer 212.

Each of the first pattern layer 221, the second pattern layer 222, and the third pattern layer 223 may be a coil pattern forming a specific inductance.

The first pattern layer 221, the second pattern layer 222, and the third pattern layer 223 are disposed on the second insulating layer 210 and connected to each other through the second through electrode 230 to form a specific inductance.

The inductance formed by the first pattern layer 221, the second pattern layer 222, and the third pattern layer 223 can be determined by a permittivity (Dk) of the second insulating layer 210, a distance (δ1, δ2) between circuit patterns disposed in different layers, and a cross-sectional area and length of each pattern layer.

The first pattern layer 221, the second pattern layer 222, and the third pattern layer 223 can have a same thickness (t1, t2, t3). In addition, a distance (δ1) between the first pattern layer 221 and the second pattern layer 222 and a distance (δ2) between the second pattern layer 222 and the third pattern layer 223 can also be the same.

Accordingly, the second substrate illustrated in FIG. 4 can be an inductor substrate that functions as an inductor having a single inductance.

Referring to FIG. 5, the second substrate of the second embodiment The substrate includes a second-first insulating layer 211a and a second-second insulating layer 212a. In addition, the second substrate of the second embodiment includes a first pattern layer 221a disposed on an upper surface of the second-first insulating layer 211a. In addition, the second substrate of the second embodiment includes a second pattern layer 222a disposed between a lower surface of the second-first insulating layer 211a and an upper surface of the second-second insulating layer 212a. In addition, the second substrate of the second embodiment includes a third pattern layer 223a disposed on a lower surface of the second-second insulating layer 212a.

At this time, the first pattern layer 221 and the third pattern layer 223 of the first embodiment have a structure protruding from the upper surface of the second-first insulating layer 211 and the lower surface of the second-second insulating layer 212, respectively.

Unlike this, the first pattern layer 221a and the third pattern layer 223a of the second embodiment may have a structure embedded in an upper surface of the second-first insulating layer 211a and a lower surface of the second-second insulating layer 212a.

To this end, the second-first insulating layer 211a and the second-second insulating layer 212a of the second embodiment may include a photocurable resin or a photosensitive resin. For example, the second-first insulating layer 211a and the second-second insulating layer 212a may be formed of a PID (Photo imageable dielectrics) material.

To this end, the second-first insulating layer 211a and the second-second insulating layer 212a may include an epoxy resin, a photo initiator, a silicon-based filler (Si filler), a curing agent, and the like. For example, the second-first insulating layer 211a and the second-second insulating layer 212a may be formed by laminating a photocurable resin film or applying a photocurable resin paste or liquid. At this time, in one example, the photocurable resin material may include at least one selected from photocurable polyhydroxystyrene (PHS), photocurable poly benzoxazole (PBO), photocurable polyimide (PI), photocurable benzocyclobutene (BCB), photocurable polysiloxane, photocurable epoxy, and novolac resin.

Through this, the embodiment forms a pattern recess (not shown) at the upper and lower surfaces of the second-first insulating layer 211a and the second-second insulating layer 212a, respectively. In addition, the embodiment allows the first pattern layer 221 and the third pattern layer 223 to be embedded in the formed pattern recess.

Referring to FIG. 6, the second substrate of the third embodiment may be an inductor substrate having multiple inductances.

The second substrate of the third embodiment includes a second-first insulating layer 211b and a second-second insulating layer 212b. In addition, the second substrate of the third embodiment includes a first pattern layer 221b disposed on an upper surface of the second-first insulating layer 211b. In addition, the second substrate of the third embodiment includes a second pattern layer 222b disposed between a lower surface of the second-first insulating layer 211b and an upper surface of the second-second insulating layer 212b. In addition, the second substrate of the third embodiment includes a third pattern layer 223b disposed on a lower surface of the second-second insulating layer 212b.

At this time, the first pattern layer 221b may include multiple coil patterns.

The first pattern layer 221b includes a first coil pattern 221b1. In addition, the first pattern layer 221b includes a second coil pattern 221b2.

The first coil pattern 221b1 and the second coil pattern 221b2 may have different arrangement structures.

For example, the first coil pattern 221b1 may have a structure embedded in an upper surface of the second-first insulating layer 211b. In addition, the second coil pattern 221b2 may have a structure protruding on the upper surface of the second-first insulating layer 211b.

Accordingly, in the second substrate of the third embodiment, a first separation distance (δ1) between the first coil pattern 221b1 and the second pattern layer 222b may be different from a second separation distance (δ2) between the second coil pattern 221b2 and the second pattern layer 222b.

The second separation distance (δ2) may be greater than the first separation distance (δ1). For example, the second separation distance (δ2) may be greater than the first separation distance (δ1) by a thickness of the first coil pattern 221b1.

Accordingly, in the second substrate of the third embodiment, the first coil pattern 221b1 and the second pattern layer 222b may form a first inductance. In addition, the second coil pattern 221b2 and the second pattern layer 222b may form a second inductance different from the first inductance.

Referring to FIG. 7, the second substrate of the fourth embodiment may be an inductor substrate having multiple inductances.

The second substrate of the fourth embodiment includes a second-first insulating layer 211c and a second-second insulating layer 212c. In addition, the second substrate of the fourth embodiment includes a first pattern layer 221c disposed on an upper surface of the second-first insulating layer 211c. In addition, the second substrate of the fourth embodiment includes a second pattern layer 222c disposed between a lower surface of the second-first insulating layer 211c and an upper surface of the second-second insulating layer 212c. In addition, the second substrate of the fourth embodiment includes a third pattern layer 223c disposed on a lower surface of the second-second insulating layer 212c.

At this time, the first pattern layer 221c may include a plurality of coil patterns.

The first pattern layer 221c may include a first coil pattern 221cl, a second coil pattern 221c2, a third coil pattern 221c3, and a fourth coil pattern 221c4.

In addition, the fourth embodiment allows different inductances to be formed by the first coil pattern 221c1, the second coil pattern 221c2, the third coil pattern 221c3, and the fourth coil pattern 221c4.

The first coil pattern 221c1 and the second pattern layer 222c may have a first separation distance (δ1). In addition, the second coil pattern 221c2 and the second pattern layer 222c may have a second separation distance (δ2). In addition, the third coil pattern 221c3 and the second pattern layer 222c may have a third separation distance (δ3). In addition, the fourth coil pattern 221c4 and the second pattern layer 222c may have a fourth separation distance (δ4).

The first coil pattern 221c1, the second coil pattern 221c2, and the third coil pattern 221c3 may have a structure embedded in the upper surface of the second-first insulating layer 211c. In addition, the fourth coil pattern 221c4 may have a structure protruding on the upper surface of the second-first insulating layer 211c.

At this time, a plurality of recesses having different depths can be formed at the upper surface of the second-first insulating layer 211c. In addition, the first coil pattern 221c1, the second coil pattern 221c2, and the third coil pattern 221c3 can be disposed in each of the recesses having different depths.

Accordingly, the embodiment may be implemented so that the first to fourth separation distances (δ1, δ2, δ3, δ4) have different values.

The semiconductor package of the embodiment includes a first substrate and a second substrate. In addition, the semiconductor package includes at least one device mounted on the first substrate. In addition, the second substrate is mounted on the first substrate and can perform an inductor function or a capacitor function.

Specifically, the embodiment configures one of the inductor and the capacitor as a die-type device, and other one of the inductor and the capacitor as a substrate-type device. Accordingly, the embodiment can secure a design space of the semiconductor package and thereby secure design freedom. Furthermore, the embodiment implements an inductor and a capacitor in different types to solve the reliability problem that may occur between the inductor and the capacitor. For example, when the inductor and the capacitor are disposed adjacent to each other, there may be a problem that the characteristics of each function are deteriorated due to the interference therebetween. Accordingly, the embodiment implements an inductor and a capacitor in different types, and it is possible to solve the problem that the characteristics of each function are deteriorated. Furthermore, the embodiment may maximize characteristics of an inductor function and a capacitor function, thereby further improving product reliability.

In addition, the embodiment includes a plurality of inductors or a plurality of capacitors. In addition, one inductor of the plurality of inductors is configured as a die-type device, and other inductor of the plurality of inductors is configured as a substrate-type device. In addition, in the embodiment, one capacitor of the plurality of capacitors is configured as a die-type device, and the other capacitor of the plurality of capacitors is configured as a substrate-type device.

Accordingly, the embodiment can further maximize the inductor function or the capacitor function, and thus further improve the product performance.

In addition, the second substrate of the embodiment includes a second insulating layer including a photosensitive material. In addition, a pattern layer of the second substrate is inserted into a recess of the second insulating layer or has a protruding structure. In addition, the recess of the second insulating layer can include a plurality of recesses having different depths, and the pattern layer can be respectively disposed in the plurality of recesses. Through this, the embodiment can implement a plurality of inductances in one second substrate. Accordingly, the embodiment can further improve the product performance.

Features, structures, effects, etc. described in the above embodiments are included in at least one embodiment, and it is not necessarily limited to only one embodiment. Furthermore, features, structures, effects, etc. illustrated in each embodiment can be combined or modified for other embodiments by those of ordinary skill in the art to which the embodiments belong. Accordingly, the contents related to such combinations and variations should be interpreted as being included in the scope of the embodiments.

In the above, the embodiment has been mainly described, but this is only an example and does not limit the embodiment, and those of ordinary skill in the art to which the embodiment pertains will appreciate that various modifications and applications not illustrated above are possible without departing from the essential characteristics of the present embodiment. For example, each component specifically shown in the embodiment can be implemented by modification. In addition, the differences related to these modifications and applications should be interpreted as being included in the scope of the embodiments set forth in the appended claims.

1. A semiconductor package comprising:
a first substrate;
a device mounted on the first substrate;
a second substrate disposed on the first substrate and spaced apart from the device in a horizontal direction; and
a molding layer disposed on the first substrate and molding the device,
wherein a height of an upper surface of the molding layer and a height of an upper surface of the second substrate are different from each other.

2-10. (canceled)

11. The semiconductor package of claim 1, wherein the upper surface of the molding layer is positioned lower than the upper surface of the second substrate.

12. The semiconductor package of claim 11, wherein the molding layer includes a through hole overlapping the second substrate in a vertical direction.

13. The semiconductor package of claim 12, wherein an inner wall of the through hole is spaced apart from the second substrate in the horizontal direction.

14. The semiconductor package of claim 1, wherein the upper surface of the molding layer is positioned higher than the upper surface of the second substrate, and
wherein the second substrate is embedded in the molding layer together with the device.

15. The semiconductor package of claim 1, wherein the device includes a device that functions as one of a capacitor or an inductor, and
wherein the second substrate includes a circuit pattern layer that functions as other one of the capacitor and the inductor.

16. The semiconductor package of claim 1, wherein the first substrate includes a first circuit pattern and a second circuit pattern spaced apart from each other along the horizontal direction,
wherein a first connection part is disposed on the first circuit pattern and a second connection part is disposed on the second circuit pattern,
wherein the device is disposed on the first connection part, and
wherein the second substrate is disposed on the second connection part.

17. The semiconductor package of claim 11, wherein the second substrate includes:
an insulating layer;
a circuit pattern layer arranged on the insulating layer;
a through electrode passing through the insulating layer along a vertical direction and connected to the circuit pattern layer; and
a protective layer disposed on the insulating layer, and
wherein the upper surface of the second substrate is an upper surface of the protective layer.

18. The semiconductor package of claim 14, wherein the second substrate includes:
an insulating layer;
a circuit pattern layer disposed on the insulating layer; and
a through electrode passing through the insulating layer along a vertical direction and connected to the circuit pattern layer; and
wherein the upper surface of the second substrate is an upper surface of the circuit pattern layer, and
wherein the molding layer is disposed to cover the insulating layer and the circuit pattern layer of the second substrate.

19. The semiconductor package of claim 15, wherein the second substrate is an inductor substrate including a coil pattern forming an inductance, and
wherein the device includes:
a first device corresponding to a capacitor; and
a second device spaced apart from the first device and corresponding to an inductor.

20. The semiconductor package of claim 15, wherein the second substrate is a capacitor substrate including a capacitor pattern forming a capacitance, and
wherein the device includes:
a first device corresponding to a capacitor; and
a second device spaced apart from the first device and corresponding to an inductor.

21. The semiconductor package of claim 17, wherein the circuit pattern layer includes a first circuit pattern layer disposed on an upper surface of the insulating layer, and a second circuit pattern layer disposed on a lower surface of the insulating layer, and
wherein the first circuit pattern layer includes a plurality of coil patterns,
wherein the plurality of coil patterns include a first coil pattern having a first separation distance from the second circuit pattern layer along a vertical direction, and a second coil pattern having a second separation distance different from the first separation distance from the second circuit pattern layer along a vertical direction.

22. The semiconductor package of claim 21, wherein the first coil pattern is disposed in a pattern recess formed at an upper surface of the insulating layer, and the second coil pattern protrudes on an upper surface of the insulating layer.

23. The semiconductor package of claim 21, wherein the first coil pattern is disposed in a first recess having a first depth formed at the upper surface of the second insulating layer, and
wherein the second coil pattern is disposed in a second recess having a second depth different from the first depth formed at the upper surface of the second insulating layer.

24. The semiconductor package of claim 23, wherein the insulating layer includes a photocurable resin.
